(19) United States
(12) Patent Application Publication
(10) Pub. No.: US 2026/0125820 A1
(43) Pub. Date: May 7, 2026

(54) PROCESS FOR MANUFACTURING A SILICON SINGLE CRYSTAL, AND SEMICONDUCTOR WAFER MADE OF SINGLE-CRYSTAL SILICON

(71) Applicant: Siltronic AG, Munich (DE)

(72) Inventors: Walter HEUWIESER, Stammham (DE); Karl MANGELBERGER, Ach (AT)

(21) Appl. No.: 19/114,474

(22) PCT Filed: Sep. 29, 2023
(86) PCT No.: PCT/EP2023/077145

§ 371 Date: Mar. 24, 2025

(30) Foreign Application Priority Data
Oct. 6, 2022 (EP) 22199997.2

(51) Int. Cl. C30B 29/06; C30B 15/04; C30B 15/14; C30B 30/04; H10D 62/834

(52) U.S. Cl. CPC C30B 29/06; C30B 15/04; C30B 15/14; C30B 30/04; H10D 62/834

(57) ABSTRACT

A method produces a single crystal of silicon by pulling the single crystal from a melt. The melt is in a crucible and includes phosphorus and boron as dopants in a ratio of not more than 0.41. The boron is in the melt with a concentration of 5.0×10¹⁴ to 2.2×10¹⁵ atoms/cm³. The single crystal has a cylindrical section having a diameter of at least 300 mm, which is surrounded by a heat shield while pulled from the melt. A lower edge of the heat shield is further than 18 mm from a melt surface. The single crystal is pulled at 8-13 rpm. A horizontal magnetic field is also applied to the melt, with a magnetic flux density of the horizontal magnetic of 2000-3000 Gs.

### CROSS REFERENCE TO RELATED APPLICATIONS

This application is a U.S. National Phase application under 35 U.S.C. § 371 of International Application No. PCT/EP2023/077145, filed on Sep. 29, 2023, and claims benefit to European Patent Application No. EP 22199997.2, filed on Oct. 6, 2022. The International Application was published in German on Apr. 11, 2024 as WO 2024/074431 A1 under PCT Article 21(2).

### FIELD

The present disclosure is directed to a method of producing a single crystal of silicon by pulling the single crystal from a melt. The present disclosure is also directed to providing a semiconductor wafer of monocrystalline silicon.

### BACKGROUND

The pulling of a single crystal of silicon from a melt by the Czochralski method comprises the pulling of a cylindrical section with uniform diameter. In general, semiconductor wafers of monocrystalline silicon are divided therefrom.

In order to avoid decreasing specific electrical resistance of a single crystal of silicon doped with boron owing to the segregation of boron with the length of the single crystal, counter-doping with phosphorus is possible.

US 2005 0 252 442 A1 describes a method of producing a single crystal of silicon, wherein the single crystal is pulled from a melt which is present in a crucible and contains phosphorus and boron as dopants in a ratio of 0.31, and wherein the single crystal is predominantly p-doped and has a cylindrical section having a diameter of about 200 mm.

Just as important as the observance of a target resistance over the length of the cylindrical section of the single crystal is that the resistance from the center up to the edge of the single crystal at any length position over the cylindrical section differs to a minimum degree from the target resistance.

EP 2 607 526 A1 describes a method of producing a single crystal of silicon, wherein the single crystal is pulled from a melt which is present in a crucible and contains phosphorus and boron as dopants in a ratio of 0.42, and wherein the single crystal is predominantly p-doped and has a cylindrical section having a diameter of about 200 mm. The radial variation of the resistance is 1.5% based on the greatest resistance measured.

### SUMMARY

In an embodiment, the present disclosure provides a method that produces a single crystal of silicon. The method includes: pulling the single crystal from a melt. The melt is present in a crucible and includes phosphorus and boron as dopants in a ratio of not more than 0.41. The boron is in the melt with a concentration of not less than 5.0×1014 atoms/cm3 and not more than 2.2×1015 atoms/cm3. The single crystal has a cylindrical section having a diameter of at least 300 mm, having a length, and being surrounded by a heat shield in a course of the pulling the single crystal from the melt. A lower edge of the heat shield has a distance of not less than 18 mm from a surface of the melt. The pulling of the single crystal is at a speed of not less than 8 rpm and not more than 13 rpm. The method also includes applying a horizontal magnetic field to the melt, the magnetic flux density of the horizontal magnetic field being not less than 2000 Gs and not more than 3000 Gs.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows an apparatus suitable for performance of a method according to an aspect of the present disclosure;

FIG. 2 shows the progression of the specific electrical resistance relative to the average resistance at the start of the cylindrical section depending on the crystallized amount (FS) of silicon in the case of an example and a counterexample; and

FIG. 3 shows the radial variation of the specific electrical resistance as a function of the crystallized amount of silicon in the case of the example and the counter example.

### DETAILED DESCRIPTION

Aspects of the present disclosure are directed to providing, for relatively large and relatively long single crystals of silicon, minimum variation in the specific electrical resistance thereof in the cylindrical section in axial and radial direction.

An aspect of the present disclosure is directed to a method of producing a single crystal of silicon by pulling the single crystal from a melt which is present in a crucible and comprises phosphorus and boron as dopants in a ratio of not more than 0.41, wherein the melt comprises boron with a concentration of not less than 5.0×10¹⁴ atoms/cm³ and not more than 2.2×10¹⁵ atoms/cm³, and the single crystal has a cylindrical section having a diameter of at least 300 mm and a length and is surrounded by a heat shield in the course of pulling from the melt, and wherein a lower edge of the heat shield has a distance of not less than 18 mm from a surface of the melt, the method comprising the pulling of the single crystal with a speed of not less than 8 rpm and not more than 13 rpm; and the applying of a horizontal magnetic field to the melt, the magnetic flux density of which is not less than 2000 Gs and not more than 3000 Gs.

According to a preferred embodiment, the melt must comprise boron with a concentration of not less than 5.0×10¹⁴ atoms/cm³ and not more than 2.2×10¹⁵ atoms/cm³ and have been counter-doped with phosphorus such that the ratio of phosphorus to boron is not more than 0.41. The ratio is preferably not greater than 0.35 and not less than 0.1.

The single crystal may have a diameter in the cylindrical section of at least 300 mm and is pulled from the melt by the Czochralski method, while being surrounded by a heat shield. According to a preferred embodiment, the distance of the lower edge of the heat shield from the melt must not be less than 18 mm. The distance is preferably 19 to 25 mm.

According to a preferred embodiment, the growing crystal is pulled out of the melt, it is rotated at a speed of not less than 8 rpm and not more than 13 rpm.

According to a preferred embodiment, during the pulling of the single crystal, a horizontal magnetic field is applied to the melt, the magnetic flux density of which is not less than 2000 gauss and not more than 3000 gauss.

If the above features are fulfilled, it is possible to separate semiconductor wafers from the pulled single crystal in which the specific electrical resistance from the center up to the edge varies by not more than 1%, based on the smallest resistance. In the case of measurement of the resistance of semiconductor wafers that are divided from the cylindrical section, an edge exclusion of 6 mm remains unconsidered. The variation of the resistance over the axial length of the cylindrical section of the single crystal is not more than 18%, based on the average resistance possessed by the first semiconductor wafer divided from the start of the cylindrical section.

In an embodiment, a cylindrical section of the single crystal has a diameter of at least 300 mm and preferably a length of at least 1500 mm.

The present disclosure also provides a semiconductor wafer of monocrystalline silicon having a diameter of at least 300 mm, which is predominantly p-doped and comprises phosphorus and boron as dopants, and the specific electrical resistance of which from the center up to the edge of the semiconductor wafer varies by not more than 1%, based on the smallest resistance.

The specific electrical resistance of the semiconductor wafer is preferably not less than 6 ohmcm and not more than 30 ohmcm.

The semiconductor wafer is preferably used for production of electronic components with NAND logic.

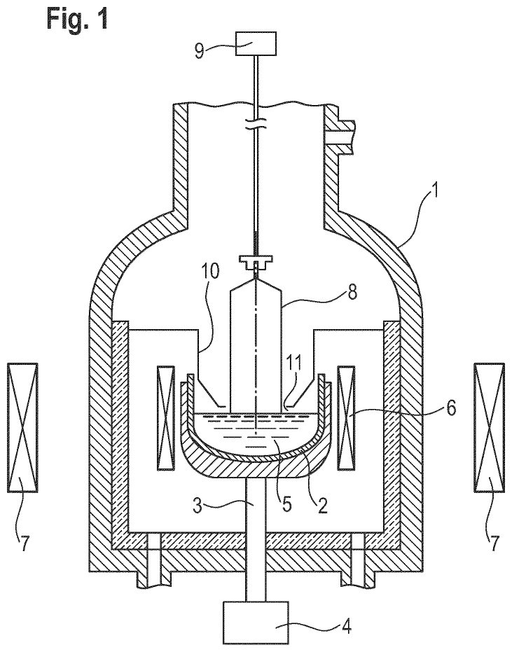

The apparatus according to FIG. 1 comprises a reactor chamber 1 that accommodates a crucible 2. The crucible 2 is supported on a shaft 3 and can be raised, lowered and rotated by means of a drive 4. The crucible 2 contains a melt 5 and is heated by means of a heating device 6 that surrounds it. The melt comprises phosphorus and boron as dopants in a ratio of not more than 0.41, and the concentration of boron is not less than 5.0×10¹⁴ atoms/cm³ and not more than 2.2×10¹⁵ atoms/cm³. Outside the reactor chamber 1 are disposed magnetic coils 7 that generate a horizontal magnetic field to which the melt is subjected. The magnetic flux density of the horizontal magnetic field is not less than 2000 Gs and not more than 3000 Gs. A single crystal 8 of silicon is pulled from the melt 5 by means of a pulling device 9, during which it is rotated about its longitudinal axis at a speed of not less than 8 rpm and not more than 13 rpm. This forms a cylindrical section with increasing length and virtually uniform diameter, from which semiconductor wafers of monocrystalline silicon are cut at a later stage. For protection from thermal radiation from the heating device 6, the single crystal 8 is surrounded by a heat shield 10. A lower edge of the heat shield 10 has a distance 11 from the surface of the melt 5 of not less than 18 mm.

The present disclosure was tested on an example and compared to a counter example.

Two single crystals of silicon with a nominal diameter of 300 mm were pulled in an apparatus having the features according to FIG. 1. In the case of the example, the dopants present in the melt were phosphorus with a concentration of 4.8×10¹⁴ atoms/cm³ and boron with a concentration of 1.29×10¹⁵ atoms/cm³, and in the case of the counterexample solely boron with a concentration of 1.2×10¹⁵ atoms/cm³.

In both cases, a horizontal magnetic field of a flux density of 2400 Gs was applied to the melt, the distance of the lower edge of the heat shield from the surface of the melt was 20 mm, and the speed at which the single crystal was rotated was 10 rpm.

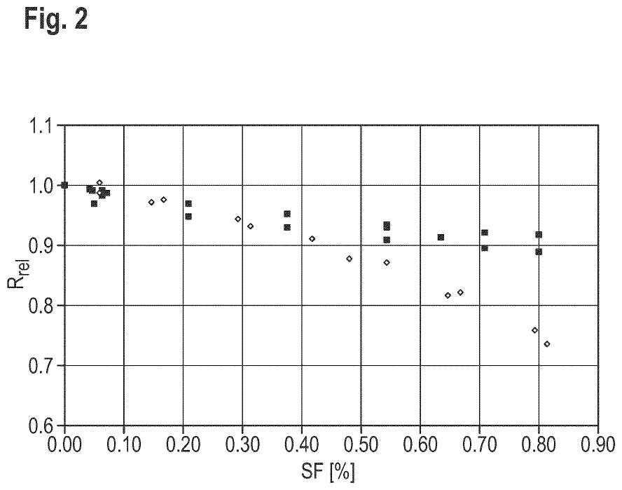

FIG. 2 shows the progression of the specific electrical resistance (Rᵣₑₗ) relative to the average resistance at the start of the cylindrical section depending on the crystallized amount (SF) of silicon in the case of the example and the counterexample.

In the case of the example, up to a crystallized amount of 80%, the resistance falls to only somewhat more than 10% of the value at the start of the cylindrical section.

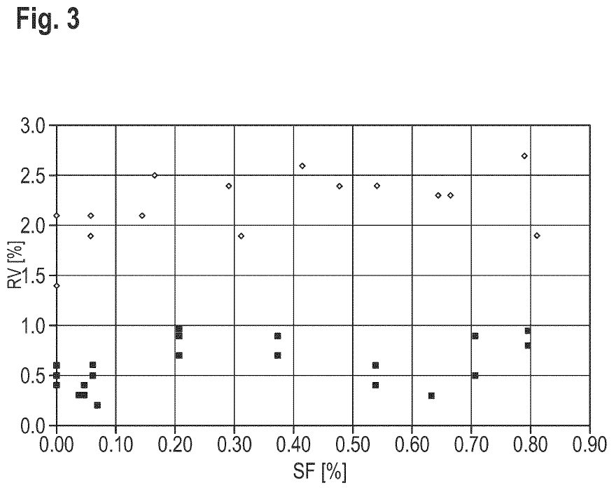

FIG. 3 shows the radial variation (RV) of the specific electrical resistance as a function of the crystallized amount (SF) of silicon in the case of the example and the counterexample. The resistance was measured according to ASTM C, and an edge exclusion of 6 mm was left unconsidered.

RV was calculated by the formula:

$$R V = ( ( {R}_{max} - {R}_{min} ) / {R}_{min} ) \times 100 \%$$

where Rₘₐₓ and Rₘᵢₙ denote the greatest and smallest resistance respectively.

In the case of the example, the radial variation from the start of the cylindrical section up to a crystallized amount of 80% remains less than 1%, based on the smallest resistance.

The semiconductor wafers of monocrystalline silicon that have been cut from the cylindrical section of the single crystal of the example had an average specific resistance in the range from 14 ohmcm to 17 ohmcm.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS USED

1 reactor chamber
2 crucible
3 shaft
4 drive
5 melt
6 heating device
7 magnetic coils
8 single crystal
9 pulling device
10 heat shield
11 distance

1. A method of producing a single crystal of silicon, the method comprising:
pulling the single crystal from a melt, the melt being present in a crucible and comprising phosphorus and boron as dopants in a ratio of not more than 0.41, the boron being in the melt with a concentration of not less than 5.0×10¹⁴ atoms/cm³ and not more than 2.2×10¹⁵ atoms/cm³, and the single crystal having a cylindrical section having a diameter of at least 300 mm, having a length, and being surrounded by a heat shield in a course of the pulling the single crystal from the melt, and a lower edge of the heat shield having a distance of not less than 18 mm from a surface of the melt, the pulling of the single crystal being at a speed of not less than 8 rpm and not more than 13 rpm; and
applying a horizontal magnetic field to the melt, a magnetic flux density of the horizontal magnetic field being not less than 2000 Gs and not more than 3000 Gs.

2. The method according to claim 1, wherein the length is at least 1500 mm.

3. The method according to claim 1, wherein the ratio is not greater than 0.35 and not less than 0.1.

4. The method according to claim 1, wherein the distance is 19 mm to 25 mm.

5. A semiconductor wafer of monocrystalline silicon having a diameter of at least 300 mm, the semiconductor wafer being predominantly p-doped, the semiconductor wafer comprising phosphorus and boron as dopants, wherein a specific electrical resistance from a center up to an edge of the semiconductor wafer varies by not more than 1%, based on a smallest resistance, and taking account of an edge exclusion of 6 mm.

6. The semiconductor wafer according to claim 5, wherein the specific electrical resistance is not less than 6 Ohmcm and not more than 30 Ohmcm.
